(19) United States
(12) Patent Application Publication
(10) Pub. No.: US 2023/0039583 A1
(43) Pub. Date: Feb. 9, 2023

(54) FLOW GUIDE COVER AND SERVER HAVING SAME

(71) Applicant: Bitmain Technologies Inc., Beijing (CN)

(72) Inventors: Yongbo GE, Beijing (CN); Mingliang HAO, Beijing (CN); Lei ZHANG, Beijing (CN); Yafang FAN, Beijing (CN); Hongyu XIU, Beijing (CN); Guohui WANG, Beijing (CN)

(73) Assignee: Bitmain Technologies Inc., Beijing (CN)

(21) Appl. No.: 17/793,421

(22) PCT Filed: Mar. 15, 2021
(86) PCT No.: PCT/CN2021/080853

§ 371 Date: Jul. 18, 2022

(30) Foreign Application Priority Data
Jan. 16, 2020 (CN) 202020101952.3

(51) Int. Cl. F04D 25/08; F04D 29/30; F04D 29/54; F04D 29/70; G06F 1/20; H05K 7/20

(52) U.S. Cl. CPC F04D 25/08; F04D 29/30; F04D 29/54; F04D 29/70; G06F 1/20; H05K 7/20

(57) ABSTRACT

The present application discloses a flow guide cover and a server having the same. The flow guide cover includes an annular frame, a flow directing member, an air collecting ring, a plurality of first air guide vanes and a plurality of second air guide vanes. The flow directing member is arranged inside the annular frame and comprises a first surface and a second surface which are arranged opposite to each other, the first surface having an area greater than that of the second surface. The air collecting ring is arranged surrounding an outer periphery of the flow directing member, located between the flow directing member and the annular frame, and spaced apart from the flow directing member and the annular frame respectively. When the flow guide cover of the present application is used in conjunction with a fan, heat can be dissipated more evenly.

### TECHNICAL FIELD

The present application relates to the technical field of heat dissipation, and in particular to a flow guide cover and a server having the same.

### BACKGROUND ART

In the related art, a part of a fan motor region is a stationary hub region (namely, a fan hub region), which is an airless region, and in which an air pressure is relatively low so that it is not conducive to heat dissipation of a chip located directly opposite the hub region; moreover, the temperature difference between the corresponding chip located in the hub region and a chip in an adjacent region can reach 7° C.-16° C., so that the flow field uniformity of a fan is poor, which is not conducive to the temperature uniformity of electronic devices such as the chips.

### SUMMARY OF THE INVENTION

The present application is intended to solve at least one of the technical problems existing in the prior art. In view of this, an objective of the present application is to provide a flow guide cover, which increases the air volume in an airless region, improves the degree of parallelism of an air flow in the airless region and the uniformity of an air flow field in the airless region, thereby improving the heat dissipation effect of a chip and an electrical element in the airless region.

Another objective of the present application is to provide a server having the flow guide cover as described above.

According to an embodiment in a first aspect of the present application, a flow guide cover comprises: an annular frame; a flow directing member arranged inside the annular frame and comprising a first surface and a second surface which are arranged opposite to each other, the first surface having an area greater than that of the second surface; an air collecting ring arranged surrounding an outer periphery of the flow directing member, located between the flow directing member and the annular frame, and spaced apart from the flow directing member and the annular frame respectively; a plurality of first air guide vanes arranged at intervals in a circumferential direction of the flow directing member and connected between the flow directing member and the air collecting ring; and a plurality of second air guide vanes arranged at intervals in a circumferential direction of the air collecting ring and connected between the air collecting ring and the annular frame.

According to the embodiment of the present application, by configuring the flow guide cover to include the annular frame, the flow directing member, the air collecting ring, the plurality of first air guide vanes and the plurality of second air guide vanes, the flow guide cover has a simple structure. When the flow guide cover is used in conjunction with a fan, the air volume in the hub region is increased, the heat dissipation effect is improved directly in front of the hub region, and the distribution of the flow field is also improved, so that the air outflow of the fan can be more uniform, and thus heat can be dissipated more evenly.

According to some embodiments of the present application, the flow directing member has a cross-sectional area gradually decreasing from the first surface to the second surface.

According to some embodiments of the present application, the flow directing member is frustum-shaped or hemispherical.

According to some embodiments of the present disclosure, the air collecting ring is of a cylindrical ring structure.

According to some embodiments of the present application, the end of the first air guide vane close to the air collecting ring deviates from the end of the first air guide vane close to the flow directing member in a radial direction of the flow directing member.

According to some embodiments of the present application, the end of the second air guide vane close to the annular frame deviates from the end of the second air guide vane close to the air collecting ring in a radial direction of the flow directing member.

According to some embodiments of the present application, the first air guide vanes are the same as the second air guide vanes in number.

According to some embodiments of the present application, the first air guide vanes correspond to the second air guide vanes on a one-to-one basis, and each first air guide vanes smoothly transitions to a respective second air guide vane.

According to some embodiments of the present application, the second air guide vanes have the same extension direction as the first air guide vanes.

According to an embodiment in a second aspect of the present application, a server comprises: a chassis; a fan assembly arranged on the chassis and comprising an air intake fan and an air discharge fan;

an electronic element arranged between the air intake fan and the air discharge fan; and a flow guide cover arranged at an air outlet of the air intake fan, wherein the flow guide cover is the flow guide cover of the embodiment in the first aspect of the present application.

According to some embodiments of the present application, the first surface faces the air intake fan, and the second surface faces the electronic element.

According to some embodiments of the present application, the air intake fan comprises a fan body and a fan casing, and the flow guide cover is mounted to the fan casing.

According to some embodiments of the present application, the flow guide cover is integrally with the fan casing by means of injection molding.

According to some embodiments of the present application, the flow guide cover is secured to the chassis.

Additional aspects and advantages of this application will be set forth in part in the following description, and in part will be apparent from the following description, or may be learned by practice of this application.

### BRIEF DESCRIPTION OF THE DRAWINGS

The above and/or additional aspects and advantages of the present application will become apparent and easily comprehensible from the following description of embodiments in conjunction with the accompanying drawings, in which:

FIG. 1 is a schematic diagram of a flow guide cover according to an embodiment of the present application;

FIG. 2 is a front view of the flow guide cover according to the embodiment of the present application;

FIG. 3 is a cross-sectional view taken along line A-A in FIG. 2;

FIG. 4 is a right side view of the flow guide cover according to the embodiment of the present application; and

FIG. 5 is a top view of the flow guide cover according to the embodiment of the present application.

Reference numerals: 100: Flow guide cover; 1: Annular frame; 2: Flow directing member; 21: First surface; 22: Second surface; 3: Air collecting ring; 41: First air guide vane; and 42: Second air guide vane.

### DETAILED DESCRIPTION OF EMBODIMENTS

Embodiments of the present application will be described below in detail, the embodiments described with reference to the accompanying drawings are exemplary, and the embodiments of the present application will be described below in detail.

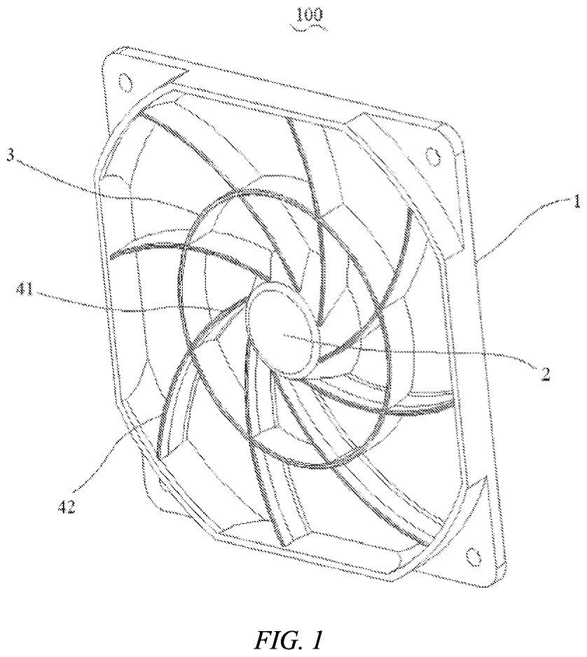

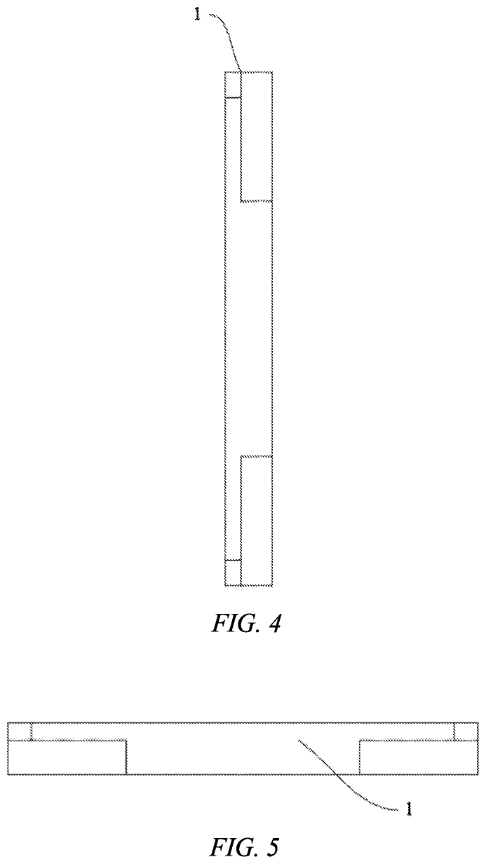

A flow guide cover 100 according to an embodiment of the present application is described below with reference to FIGS. 1 to 5.

As shown in FIGS. 1 to 5, the flow guide cover 100 according to the embodiment in the first aspect of the present application comprises an annular frame 1, a flow directing member 2, an air collecting ring 3, a plurality of first air guide vanes 41 and a plurality of second air guide vanes 42.

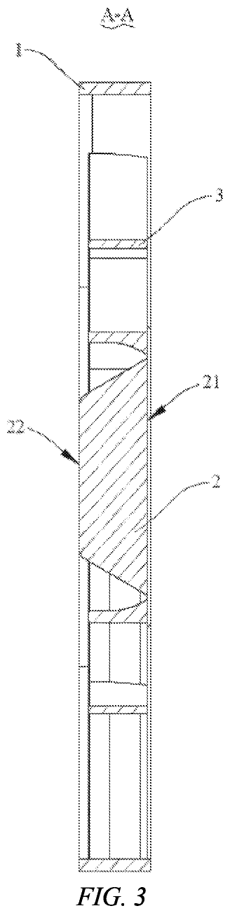

Specifically, the flow directing member 2 is arranged inside the annular frame 1. It should be noted herein that the direction “inside” can be understood as a direction toward the center of the annular frame 1, and the opposite direction thereof, which is defined as “outside”, is away from the center of the annular frame 1. In a thickness direction of the flow guide cover 100, the cross-sectional area of one end (e.g., the left end in FIG. 3) of the flow directing member 2 is smaller than that of the other end (e.g., the right end in FIG. 3) of the flow directing member 2. Specifically, the flow directing member 2 includes, in a flow direction of an airflow, a first surface 21 and a second surface 22 which are arranged opposite to each other. The first surface 21 has an area greater than that of the second surface 22. The air collecting ring 3 surrounds an outer periphery of the flow directing member 2, and the air collecting ring 3 is located between the flow directing member 2 and the annular frame 1 and is spaced apart from the flow directing member 2 and the annular frame 1 respectively. The plurality of first air guide vanes 41 are arranged at intervals in a circumferential direction of the flow directing member 2 and are connected between the flow directing member 2 and the air collecting ring 3; and the plurality of second air guide vanes 42 are arranged at intervals in a circumferential direction of the air collecting ring 3 and are connected between the air collecting ring 3 and the annular frame 1.

For example, in the example shown in FIGS. 1 to 5, the annular frame 1 is substantially of a box-shaped structure, the flow directing member 2 may be centrally located inside the annular frame 1, and the area of the first surface 21 of the flow directing member 2 is greater than that of the second surface 22. In practical applications, the flow guide cover 100 is arranged on an air discharge side of a fan (not shown), the first surface 21 of the flow directing member 2 faces the fan, and the area of the first surface 21 is greater than that of the second surface 22, so that the flow directing member 2 can direct the air blown by the fan to a hub region, the air volume in the hub region can then be increased, and heat dissipation of an electronic element such as a chip, which is directly opposite the hub region, can thus be better achieved.

The air collecting ring 3 is arranged between the flow directing member 2 and the annular frame 1, and the air collecting ring 3 is arranged surrounding the flow directing member 2. When blades of the fan rotate, the air will be dispersed all around under the action of a centrifugal force, which is not conducive to the heat dissipation of electronic devices which are directly opposite the hub region; however, the arrangement of the flow directing member 2, the air collecting ring 3, the first air guide vanes 41 and the second air guide vanes 42 makes it possible for the dispersed airflow to be reduced, and makes the degree of parallelism of the airflow better and a flow field more uniform, thereby improving the heat dissipation effect of the hub region. As shown in FIG. 1, eight first air guide vanes 41 and eight second air guide vanes 42 are respectively provided, the eight first air guide vanes 41 are arranged at intervals in the circumferential direction of the flow directing member 2 and are connected between the flow directing member 2 and the air collecting ring 3, and the eight second air guide vanes 42 are arranged at intervals in the circumferential direction of the air collecting ring 3 and are connected between the air collecting ring 3 and the annular frame 1, so that an air outflow can be separated, the degree of parallelism of the air outflow of the fan can be further improved, the flow field can be more uniform, and the dimension in the thickness direction of the flow guide cover 100 can be effectively reduced. It should be noted that the number of first air guide vanes 41 and the number of second air guide vanes 42 are not limited by this embodiment and the accompanying drawings.

According to the embodiment of the present application, by configuring the flow guide cover 100 to include the annular frame 1, the flow directing member 2, the air collecting ring 3, the plurality of first air guide vanes 41 and the plurality of second air guide vanes 42, the flow guide cover 100 has a simple structure. When the flow guide cover 100 is used in conjunction with a fan, the air volume in the hub region is increased, the heat dissipation effect is improved directly in front of the hub region, and the distribution of the flow field is also improved, so that the air outflow of the fan can be more uniform, and thus heat can be dissipated more evenly.

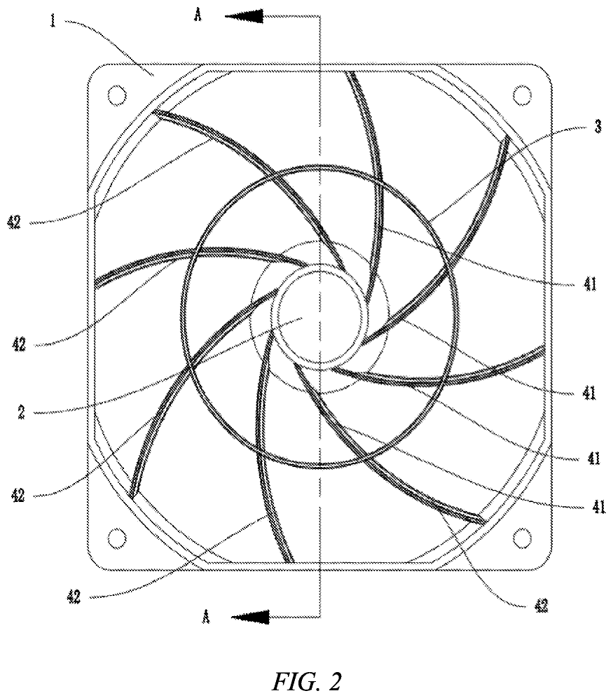

According to some embodiments of the present application, the flow directing member 2 has a cross-sectional area gradually decreasing from the first surface 21 to the second surface 22. For example, referring to FIGS. 1 and 2 in combination with FIG. 3, the cross-sectional area of the flow directing member 2 gradually varies in an axial direction thereof, the cross-sectional area of the end of the flow directing member 2 facing the fan is greater than that of the end of the flow directing member 2 away from the fan. That is to say, the area of the first surface 21 is greater than that of the second surface 22. As a result, a viscous force between the air and the flow directing member 2 is effectively used to direct the air blown by the fan to the hub region in the middle, so that the air volume in the middle hub region is increased.

In some optional embodiments, the flow directing member 2 is frustum-shaped (as shown in FIGS. 1 to 3) or hemispherical (not shown), but is not limited thereto. With such an arrangement, machining is simple, and the cost is reduced.

In some optional embodiments, the air collecting ring 3 is of a cylindrical ring structure, but is not limited thereto. For example, as shown in FIGS. 1 and 2, the air collecting ring 3 is arranged surrounding the outer periphery of the flow directing member 2, and the air collecting ring 3 is located between the flow directing member 2 and the annular frame 1 and is spaced apart from the flow directing member 2 and the annular frame 1 respectively. Due to the action of a centrifugal force, the air blown by the fan is dispersed all around, resulting in a small air volume in the hub region, so that the heat dissipation effect of the electronic devices such as chips in this region is poor; however, by arranging the air collecting ring 3, the dispersed airflow can be reduced, the air volume in the hub region and the degree of parallelism of the airflow can be increased, the uniformity of the air flow field can be ensured, and the heat dissipation effect of the electronic devices such as chips in the hub region can be improved.

According to some embodiments of the present application, the end of each first air guide vane 41 close to the air collecting ring 3 deviates from the end of the first air guide vane 41 close to the flow directing member 2 in the radial direction of the flow directing member 2, and the end of each second air guide vane 42 close to the annular frame 1 deviates from the end of the second air guide vane 42 close to the air collecting ring 3 in the radial direction of the flow directing member 2. With reference to FIGS. 1 and 2, each of the first air guide vanes 41 and each of the second air guide vanes 42 may substantially in an arc shape, and the extension directions of each of the first air guide vanes 41 and each of the second air guide vanes 42 deviate from the radial direction of the flow directing member 2. With such an arrangement, the first air guide vanes 41 and the second air guide vanes 42 have a guiding effect on the air flowing thereover, so that heat dissipation of the electronic devices such as the chips in the hub region can be better achieved.

As an implementation, the first air guide vanes 41 are the same as the second air guide vanes 42 in number. It can be understood that in other embodiments, it is also possible that the first air guide vanes 41 are different from the second air guide vanes 42 in number.

As an implementation, the first air guide vanes 41 correspond to the second air guide vanes 42 on a one-to-one basis, and each first air guide vanes 41 smoothly transitions to a respective second air guide vane 42. Each first air guide vane 41 smoothly transitioning to a respective second air guide vane 42 means that the connection between the first air guide vane 41 and the second air guide vane 42 extends in an extension direction of the first air guide vane 41 and transitions to the second air guide vane 42. With this arrangement, the first air guide vane 41 and the second air guide vane 42 may be integrally formed, thereby reducing the number of manufacturing processes and reducing the cost. As an alternative implementation, it is also possible that the first air guide vanes 41 are not arranged corresponding to the second air guide vanes 42, that is, the first air guide vanes 41 and the second air guide vanes 42 are arranged in a staggered manner rather than smooth transition. It can be understood that the specific numbers and specific arrangements of the first air guide vanes 41 and the second air guide vanes 42 can be specifically set according to actual requirements, so as to better achieve practical applications.

As an implementation, the second air guide vanes 42 have the same extension direction as the first air guide vanes 41. When the second air guide vanes 42 have the same extension direction as the first air guide vanes 41, the second air guide vanes 42 have the same curvature as the corresponding first air guide vanes 41. In this way, the degree of parallelism of the air flow in the hub region can be further ensured while the machining of the first air guide vanes 41 and the second air guide vanes 42 is facilitated. Of course, the present application is not limited thereto, and it is also possible that the second air guide vanes 42 have a different extension direction from the first air guide vanes 41.

According to an embodiment in a second aspect of the present application, a server (not shown) includes a chassis (not shown), a fan assembly (not shown), an electronic element (not shown), and a flow guide cover 100. The flow guide cover 100 is the flow guide cover 100 according to the embodiment in the first aspect of the present application described above.

Specifically, the fan assembly is arranged on the chassis, and the fan assembly comprises an air intake fan and an air discharge fan. The flow guide cover 100 is arranged at an air outlet of the air intake fan, and the electronic element is arranged between the air intake fan and the air discharge fan. The electronic element may be a chip or other elements.

According to the server in the embodiment of the present application, by arranging the flow guide cover 100 at the air outlet of the air intake fan, the flow guide cover 100 can effectively guide the air from the air outlet to the inside of the chassis, and achieve the adjustment of the air outflow from the air intake fan, thereby improving the airless condition in the hub region of the air intake fan, and improving the uniformity of the air outflow. Furthermore, by arranging the flow guide cover 100, the average temperature of all the chips at the air discharge fan can be about 1° C. lower compared with a conventional server without the flow guide cover 100, so that heat from the electronic devices such as the chips at the hub region can be effectively dissipated.

As an implementation, the first surface 21 faces the air intake fan, and the second surface 22 faces the electronic element. The area of the first surface 21 is greater than that of the second surface 22, so that the flow directing member 2 can direct the air blown by the air intake fan to the hub region, the air volume in the hub region can then be increased, and heat dissipation of the electronic element, which is directly opposite the hub region, can thus be better achieved.

As an implementation, the air intake fan includes a fan body and a fan casing, and the flow guide cover 100 is mounted to the fan casing. Of course, as another implementation, the flow guide cover 100 may also be secured to the chassis. In this case, the flow guide cover 100 may be separated from the fan, and the flow guide cover 100 may be machined and then mounted directly (e.g., in a plugging manner) into the chassis. Thus, the production process is simple, and quick mounting can be achieved. For example, slot locations may be reserved in the flow guide cover 100 so that the flow guide cover 100 is suitable for a variety of fans.

According to some embodiments of the present application, the flow guide cover 100 is integrally with the fan casing by means of injection molding. In this case, the flow guide cover 100 and the fan casing are made of an integral structure. With such an arrangement, the fan is prevented from being excessively thick, facilitating the miniaturized design of the server.

Other configurations and operations of the server according to the embodiments of the present application are known to those of ordinary skill in the art, and details are not described herein.

In the description of the present application, it should be understood that orientation or position relationships indicated by terms such as “center”, “length”, “width”, “thickness”, “up”, “down”, “front”, “rear”, “left”, “right”, “top”, “bottom”, “inside”, “outside”, “axial”, “radial”, and “circumferential” are based on orientation or position relationships shown in the accompanying drawings and are merely for ease of description of the present application and simplification of the description, rather than indicating or implying that the apparatuses or elements referred to must have a specific orientation or be constructed and operated in a specific orientation, and therefore cannot be construed as limiting the present application.

In the description of the present application, it should be noted that unless otherwise explicitly specified and defined, terms “mounting”, “connecting” and “connection” should be understood in a broad sense, for example, they may be a fixed connection, a detachable connection, or an integrated connection, or may be a direct connection, an indirect connection by means of an intermediate medium, or internal communication between two elements. For those of ordinary skill in the art, the specific meaning of the terms mentioned above in the present application can be construed according to specific circumstances.

In the description of the specification, the description with reference to terms such as “an embodiment”, “some embodiments”, “a schematic embodiment”, “an example”, “a specific example”, or “some examples” means that specific features, structures, materials, or characteristics described in combination with the embodiments or examples are included in at least one embodiment or example of the present application. In this specification, the schematic expressions of the above terms do not necessarily refer to the same embodiments or examples.

Although the embodiments of the present application have been shown and described, those of ordinary skill in the art can understand that various changes, modifications, substitutions, and variations can be made to these embodiments without departing from the principles and spirit of the present application. The scope of the present application is defined by the claims and equivalents thereof.

1. A flow guide cover, comprising:
an annular frame;
a flow directing member arranged inside the annular frame and comprising a first surface and a second surface which are arranged opposite to each other, the first surface having an area greater than that of the second surface;
an air collecting ring arranged surrounding an outer periphery of the flow directing member, located between the flow directing member and the annular frame, and spaced apart from the flow directing member and the annular frame respectively;
a plurality of first air guide vanes arranged at intervals in a circumferential direction of the flow directing member and connected between the flow directing member and the air collecting ring; and
a plurality of second air guide vanes arranged at intervals in a circumferential direction of the air collecting ring and connected between the air collecting ring and the annular frame.

2. The flow guide cover of claim 1, wherein the flow directing member has a cross-sectional area gradually decreasing from the first surface to the second surface.

3. The flow guide cover of claim 1, wherein the flow directing member is frustum-shaped or hemispherical.

4. The flow guide cover of claim 1, wherein the air collecting ring is of a cylindrical ring structure.

5. The flow guide cover of claim 1, wherein the end of the first air guide vane close to the air collecting ring deviates from the end of the first air guide vane close to the flow directing member in a radial direction of the flow directing member.

6. The flow guide cover of claim 1, wherein the end of the second air guide vane close to the annular frame deviates from the end of the second air guide vane close to the air collecting ring in a radial direction of the flow directing member.

7. The flow guide cover of claim 1, wherein the first air guide vanes are the same as the second air guide vanes in number.

8. The flow guide cover of claim 7, wherein the first air guide vanes correspond to the second air guide vanes on a one-to-one basis, and each first air guide vanes smoothly transitions to a respective second air guide vane.

9. The flow guide cover of claim 8, wherein the second air guide vanes have the same extension direction as the first air guide vanes.

10. A server, comprising:
a chassis;
a fan assembly arranged on the chassis and comprising an air intake fan and an air discharge fan;
an electronic element arranged between the air intake fan and the air discharge fan; and
a flow guide cover arranged at an air outlet of the air intake fan, wherein the flow guide cover is the flow guide cover of claim 1.

11. The server of claim 10, wherein the first surface faces the air intake fan, and the second surface faces the electronic element.

12. The server of claim 10, wherein the air intake fan comprises a fan body and a fan casing, and the flow guide cover is mounted to the fan casing.

13. The server of claim 12, wherein the flow guide cover is integrally with the fan casing by means of injection molding.

14. The server of claim 10, wherein the flow guide cover is secured to the chassis.

15. The flow guide cover of claim 2, wherein the flow directing member is frustum-shaped or hemispherical.

16. The flow guide cover of claim 2, wherein the air collecting ring is of a cylindrical ring structure.

17. The flow guide cover of claim 5, wherein the first air guide vanes are the same as the second air guide vanes in number.

18. The flow guide cover of claim 6, wherein the first air guide vanes are the same as the second air guide vanes in number.

19. The server of claim 11, wherein the air intake fan comprises a fan body and a fan casing, and the flow guide cover is mounted to the fan casing.

20. The server of claim 11, wherein the flow guide cover is secured to the chassis.
